(19) United States
(12) Patent Application Publication
(10) Pub. No.: US 2021/0167038 A1
(43) Pub. Date: Jun. 3, 2021

(54) DUAL IN-LINE MEMORY MODULE

(71) Applicant: Hewlett Packard Enterprise Development LP, Houston, TX (US)

(72) Inventors: Gregg B. Lesartre, Fort Collins, CO (US); Jason H. Culler, Livermore, CO (US); Martin Foltin, Fort Collins, CO (US); William S. Jaffe, Fort Collins, CO (US)

(21) Appl. No.: 17/248,988

(22) Filed: Feb. 16, 2021

Related U.S. Application Data
(63) Continuation of application No. 16/075,962, filed on Aug. 6, 2018.

(51) Int. Cl. H01L 25/065; H01L 25/18

(52) U.S. Cl. CPC H01L 25/0652; H01L 25/18; H01L 2225/06541; H01L 2225/0651; H01L 2225/06513; H01L 2225/06517

(57) ABSTRACT

According to an example, a dual in-line memory module (DIMM) may include a high density package substrate including a plurality of connectors for communicatively interconnecting the DIMM to a system.

### BACKGROUND

A dual in-line memory module (DIMM) may include a series of dynamic random-access memory integrated circuits. These modules may be mounted on a printed circuit board (PCB), and designed for use in personal computers, workstations, and servers.

### BRIEF DESCRIPTION OF DRAWINGS

Features of the present disclosure are illustrated by way of example and not limited in the following figure(s), in which like numerals indicate like elements, in which:

FIG. 1A illustrates a front sectional view of a dual in-line memory module (DIMM), according to an example of the present disclosure;

FIG. 1B illustrates a top view of the DIMM of FIG. 1A, according to an example of the present disclosure;

FIG. 2 illustrates a front sectional view of a DIMM, according to an example of the present disclosure; and

FIG. 3 illustrates a flowchart of a method for implementing a DIMM, according to an example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

A DIMM may be built by placing packaged memory and other devices on an epoxy reinforced PCB laminate board. The PCB laminate board may be described as a multi-layer copper and dielectric board that mechanically supports and electrically connects many different components. An example of a component may include a die mounted on a substrate that is then attached to the PCB. Memory capacities offered on a DIMM may be limited by physical and cooling constraints imposed by the need for packages larger than the intrinsic footprint and height of a die and die stacks, and by the minimum geometries supported by a PCB. Large via keepout areas, wire width, and spacing rule dimensions used in PCB technologies may also limit wiring densities.

A DIMM form factor may provide for connection of memory boards to a processor. With respect to the DIMM form factor, as more memory components and memory support functions are increasingly implemented onto the DIMM form factor, meeting thermal, volumetric, on-DIMM signal integrity, and on-DIMM routing specifications can be challenging.

The DIMM form factor provides minimal space for stacking components, which results in consumption of space that is also needed for air flow to provide cooling. For example, a 30 mm×130 mm DIMM form factor may include a high aspect ratio, which may add challenges to signal routing density. These aspects and PCB wire density can make it challenging to fit the needed wires through a PCB. For example, for a separately packaged high input/output (I/O) count on-DIMM controller where signals are to be routed from the controller package onto the DIMM PCB, these challenges may be increasingly prevalent. The result is that a relatively larger controller package may be needed to divide the signals sufficiently before passing through ball grid arrays (BGAs) to the PCB such that there is sufficient room to route all signals to their destinations. BGAs may be described as spherical solder “balls” used to connect a wirebond or flip chip component to a PCB. With respect to the need for the relatively larger controller package to divide the signals sufficiently before passing through BGAs to the PCB, these aspects may create sub-optimal signal routes from a signal integrity point of view, and result in inefficient use of a DIMM board area.

In order to address the aforementioned technical challenges with respect to DIMM form factor, a memory subsystem implementation is disclosed herein (e.g., a 2.5D or 3D packaged controller and memory may be utilized as a DIMM as disclosed herein), where a plurality of memory die or memory die stacks and controller application specific integrated circuits (ASICs) are integrated directly on a single high density package substrate that also includes a gold finger connector edge compliant with a DIMM standard. These aspects may eliminate the need for PCB and BGA solder balls, and avoid area, routing, and via density challenges, as well as component height challenges as disclosed herein.

By removing the PCB and using the high density package substrate as a main board or carrier, the integration ladder may be modified by removing an additional physical interconnect layer between the gold fingers and the wirebond or flip-chip die as disclosed herein. By inclusion of Through Silicon Vias (TSV) as disclosed herein, direct memory and controller die stacking may be achieved with high density flip-chip electrical connections. The TSV memory stacks and/or the memory die and controller die stacks may be directly placed on the substrate/package DIMM with gold fingers as disclosed herein.

As disclosed herein, a DIMM is provided that may benefit from the higher density of a package substrate. The high density package substrate technology may include finer (i.e., as opposed to coarser) features and structures (e.g., lines, spacing between features, vias, via keepouts, etc.) compared to PCB technology due to advanced manufacturing processes and equipment. The high density package substrate may differ from other substrates in at least the following aspects. The high density package substrate may include gold fingers compliant with a DIMM standard. In this regard, connection to a PCB using BGA solder balls or wire leads is eliminated. Further, according to examples, use of a PCB may be eliminated. The high density package substrate may be inserted directly into a system board DIMM connector. The method of connecting the high density package substrate to a system may also be different as disclosed herein. The substrate size may be compliant with a DIMM form factor standard.

The high density package substrate may be described as a ceramic or organic multi-layer copper and dielectric carrier that is the physical and electrical interface between a wirebond or flip chip die and electrical connectors (e.g., gold fingers) provided on the high density package substrate. For a wirebond die, signal and power connection pads may be placed around the outer edges of the die, and the die may be mounted face (pads and circuits) up onto a substrate using an adhesive. For a flip chip die, pads may be placed in a full area array, signal and power connection pads may be placed anywhere, and the die may be “flipped” and placed face (pads, bumps, and circuits) down onto a substrate. For the high density package substrate, a fine pitch wirebond or flip chip die may be mounted and electrically connected directly to the high density package substrate. For the high density package substrate, very fine features (signal lines, vertical vias, etc.) may be realized and thus may support mounting and connection of die devices with very fine pitch signal and power connections.

While a high density package substrate solution may be higher cost than a PCB based DIMM, the elimination of the cost of separate packaging solutions for the controller and memories may offset this cost. Fewer materials (e.g., elimination of the substrate between BGAs, and the BGAs) may also result in shorter stacks, and a relatively more efficient thermal solution by opening up more air flow with the shorter overall height. Short traces may also save power and enhance signaling performance. Further, smaller component footprints may increase room for higher capacities and capabilities.

Removing the substrate for wirebond and flip chip devices on the PCB (i.e., the substrate between the wirebond and flip chip dies and BGAs) may address issues in all dimensions. For example, direct die attachment to the high density package substrate may save valuable real estate in the X and Y dimensions on the top and bottom side of the DIMM. Further, direct die attachment to the high density package substrate may save Z thickness issues by removing the original substrate and BGA balls.

With respect to the high density package substrate, thinner dielectric layers may allow for thin signal line widths (thus high routing density). Further, the high density package substrate may provide for very fine copper features (e.g., minimum line widths down to 10 um, small vertical via dimensions (e.g., to provide for routing and connection to die with very small bump or wirebond pad pitches (below 100 um for example)). The high density package substrate may also provide for routing density that is orders of magnitude greater than DIMMs based on PCB technology.

Use of the high density package substrate as the main board for DIMMs may eliminate separate wirebond and flip chip substrates, and the associated BGA balls (thus reducing total solution Z thickness). Elimination of the wirebond and flip chip substrates may provide for higher availability of the main “board” area to use for other devices, or the main “board” size may be reduced. Elimination of the wirebond and flip chip substrates may provide for increased signal integrity (SI), for example, based on a cleaner transmission path for the signals. For example, the additional substrate and BGA balls in the signal transmission path for DIMMS based on PCB technology may result in an increase in the frequency dependent loss (i.e., insertion loss (IL)), and may generally create an increase in return loss (RL) due to impedance discontinuities.

Use of the high density package substrate may provide for smaller high density signal routes that take less power to drive, resulting in a reduction in the total system power. With the increase in signal route density, the number of connections between devices may be doubled for example, and then driven at one-half the speed to maintain the same connection bandwidth, but with a resulting decrease in power. Elimination of the wirebond and flip chip substrates and the BGA balls may result in a reduction of the resistance and inductance of the power delivery network (PDN) components, such as the wirebond and flip chip dies, package, PCB, power devices, etc., thus increasing the performance of the PDN. With the large increase in top and bottom main board space, relatively large amounts of capacitors may be placed around various devices, for example, to provide for storage and protection of data during an unexpected system power down.

Use of the high density package substrate may provide for increased system reliability. For example, by eliminating the wirebond and flip chip substrates and the BGA balls, the total number of solder joints (which may be a failure point) and interconnect devices are reduced, and thus increasing the total system reliability. Use of the high density package substrate may provide for increased thermal control. For example, a reduction in the total thickness may provide for more room for thermal design components (e.g., heat sinks, over-mold, etc.) and/or increases air flow. Use of the high density package substrate may also provide for the availability of a greater amount of area on the top and bottom side of the main board, thus providing additional area for other devices, or reduction in the total size of the main board (i.e., the board defined by the high density package substrate and electrical connectors).

According to examples, a DIMM is disclosed herein and may include a high density package substrate including a plurality of connectors for communicatively interconnecting the DIMM to a system (e.g., a server, etc.). A device including a first die including a plurality of wirebonds and associated wirebond pads may directly interface with the high density package substrate, and/or a second die including a plurality of connection pads may directly interface with the high density package substrate. A connector of the plurality of connectors may be directly connected to the device respectively via a wirebond of the plurality of wirebonds and/or a connection pad of the plurality of connection pads. According to examples, the first die may include a wirebond die. According to examples, the second die may include a flip chip die. According to examples, the connectors may include gold fingers. According to examples, for the device that includes the first die, the DIMM may further include a plurality of wirebond dies including the wirebond die, where each of the wirebond dies includes a plurality of wirebonds to directly interface with the high density package substrate. According to examples, the plurality of wirebond dies may be disposed in a stacked configuration. According to examples, for the device that includes the first die and the second die, the DIMM may further include a plurality of high density die to die routes between the wirebond die and the flip chip die. According to examples, for the device that includes the second die, the DIMM may further include a plurality of high density die to gold finger routes between the flip chip die and a gold finger of the plurality of gold fingers.

According to examples, a DIMM is disclosed herein and may include a high density package substrate including a plurality of connectors for communicatively interconnecting the DIMM to a system. Furthermore, the DIMM may include a plurality of stacked memory dies connected with each other, for example, by TSV, and connected to the DIMM, for example, by Copper pillars or other similar technology. According to examples, each of the plurality of stacked wirebond memory dies may include a plurality of wirebonds and associated wirebond pads to directly interface with the high density package substrate and/or a flip chip controller ASIC die including a plurality of connection pads to directly interface with the high density package substrate. A connector of the plurality of connectors may be directly connected to the device respectively via a wirebond of the plurality of wirebonds and/or a connection pad of the plurality of connection pads.

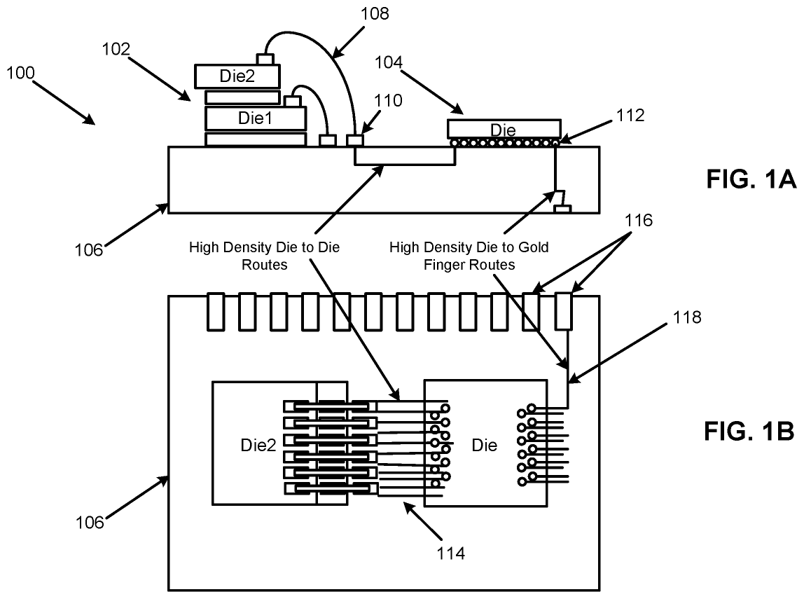

FIG. 1A illustrates a front sectional view of a DIMM 100, according to an example of the present disclosure. FIG. 1B illustrates a top view of the DIMM 100, according to an example of the present disclosure.

Referring to FIGS. 1A and 1B, the DIMM 100 may include packaged components (e.g., a wirebond die 102 and a flip chip die 104 (for the controller ASIC)) placed on a high density package substrate 106. The wirebond die 102 may be wirebonded at 108 (e.g., via wirebond pads 110) directly to the high density package substrate 106. The flip chip die 104 may include a plurality of connection pads 112 to directly interface with the high density package substrate 106. With respect to die to die routes, high density die to die routes 114 may be used for interconnection between different dies (e.g., the wirebond die 102 and the flip chip die 104). The flip chip die 104 may be interconnected to gold fingers 116 of the high density package substrate 106 using high density die to gold finger routes 118. Thus, compared to a PCB where a wirebond die and a flip chip die are connected to intermediate substrates, and then connected to BGAs to connect to the PCB, the wirebond die 102 and the flip chip die 104 may be directly connected to the high density package substrate 106.

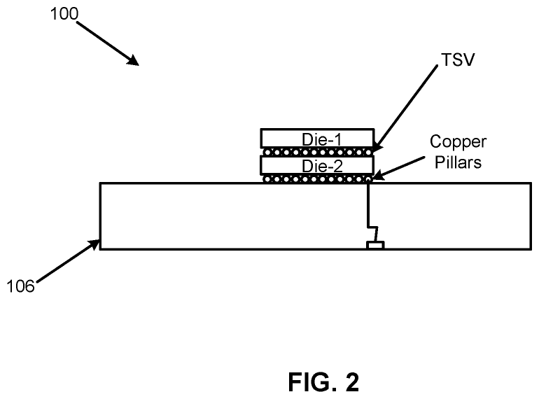

FIG. 2 illustrates a front sectional view of a DIMM, according to an example of the present disclosure. According to examples, as illustrated in FIG. 2, the high density package substrate 106 may include a first die and a second die that are connected to each other by TSV, where the second die that is adjacent the high density package substrate 106 is connected to the high density package substrate 106 by Copper pillars (or other similar technology).

Thus, the DIMM 100 may be implemented as a 2.5D package with gold fingers connecting directly from a 2.5D substrate (i.e., the high density package substrate 106) to a system DIMM slot. Thus, signals and power may be routed to DIMM specification compliant gold fingers to allow for insertion into a standard DIMM slot.

As illustrated in FIG. 1A, memories (e.g., the wirebond dies 102, which may also be designated wirebond memory dies) may be mounted on the high density package substrate 106. As also illustrated in FIG. 1A, memories may be stacked in packages that are then mounted on the high density package substrate 106. In this regard, memories may be stacked directly on the high density package substrate 106 with wirebonds connecting directly between the high density package substrate 106 and the memory die.

A DIMM controller may be flip chip attached (e.g., by the flip chip die 104) directly to the high density package substrate 106, providing direct connectivity between controller application specific integrated circuit (ASIC) C4 contacts to the finer wire pitch of the high density package substrate 106, densely routing to the components on the high density package substrate 106 and to the gold fingers 116. The C4 contacts may represent a controlled collapse chip connection, and include spherical solder “bumps” used for flip chip die connection to the high density package substrate 106.

Additional components, such as voltage regulators, microcontrollers, data buffers, resistors, capacitors, etc., may also be mounted directly to the high density package substrate 106. The entire assembly may then be covered and encased in appropriately thermally conductive material, and provided as needed with a heat spreader or other heat dissipation solution. The result is a DIMM 100 that benefits for the higher density provided by the use of the high density package substrate 106.

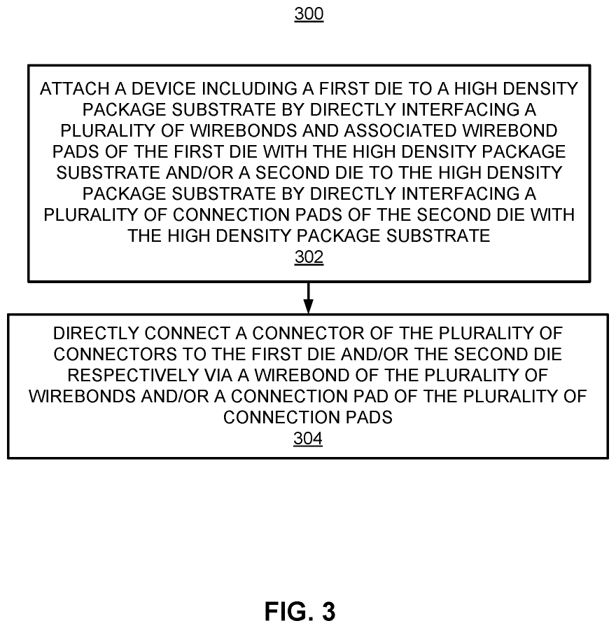

FIG. 3 illustrates a flowchart of method 300 for implementing a DIMM, corresponding to the example of the DIMM 100 whose construction is described in detail above. The method 300 may be implemented on the DIMM 100 with reference to FIGS. 1A and 1B by way of example and not limitation. The method 300 may be practiced in other apparatus.

Referring to FIGS. 1A-3, for the method 300, at block 302, the method may include attaching a device including a first die to a high density package substrate by directly interfacing a plurality of wirebonds and associated wirebond pads of the first die with the high density package substrate and/or a second die to the high density package substrate by directly interfacing a plurality of connection pads of the second die with the high density package substrate. The high density package substrate may include a plurality of connectors for communicatively interconnecting the DIMM to a system. For example, referring to FIGS. 1A and 1B, the first die (e.g., the wirebond die 102) may be attached to the high density package substrate 106 by directly interfacing a plurality of wirebonds 108 and associated wirebond pads 110 of the first die with the high density package substrate 106. The high density package substrate 106 may include a plurality of connectors (e.g., the gold fingers 116) for communicatively interconnecting the DIMM to a system (e.g., a server, etc.). Further, referring to FIGS. 1A and 1B, the second die (e.g., the flip chip die 104) may be attached to the high density package substrate 106 by directly interfacing a plurality of connection pads 112 of the second die with the high density package substrate 106.

At block 304, the method may include directly connecting a connector of the plurality of connectors to the device respectively via a wirebond of the plurality of wirebonds and/or a connection pad of the plurality of connection pads. For example, referring to FIGS. 1A and 1B, a connector (e.g., one of the gold fingers 116) of the plurality of connectors (e.g., the gold fingers 116) may be directly connected to the first die and/or the second die respectively via a wirebond of the plurality of wirebonds 108 and a connection pad of the plurality of connection pads 112.

According to examples, for the device including the first die and the second die, the method 300 may further include interconnecting the first die to the second die by a plurality of high density die to die routes 114.

According to examples, for the device including the second die, the method 300 may further include interconnecting the second die to a connector of the plurality of connectors by a plurality of high density die to connector routes 118.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A dual in-line memory module (DIMM) comprising:
a high density package substrate including a plurality of connectors for communicatively interconnecting the DIMM to a system; and
a device including at least one of
a first die including a plurality of wirebonds and associated wirebond pads to directly interface with the high density package substrate, and
a second die including a plurality of connection pads to directly interface with the high density package substrate,
wherein a connector of the plurality of connectors is directly connected to the device respectively via at least one of a wirebond of the plurality of wirebonds and a connection pad of the plurality of connection pads.

2. The DIMM according to claim 1, wherein the plurality of connectors include gold fingers.

3. The DIMM according to claim 1, for the device that includes the first die, wherein the first die is a wirebond die, further comprising:
a plurality of wirebond dies including the wirebond die, wherein each of the plurality of wirebond dies includes a plurality of wirebonds to directly interface with the high density package substrate.

4. The DIMM according to claim 3, wherein the plurality of wirebond dies are disposed in a stacked configuration.

5. The DIMM according to claim 1, for the device that includes the first die and the second die, wherein the first die is a wirebond die and the second die is a flip chip die, further comprising:
a plurality of high density die to die routes between the wirebond die and the flip chip die.

6. The DIMM according to claim 1, for the device that includes the second die, wherein the second die is a flip chip die, and the plurality of connectors include a plurality of gold fingers, further comprising:
a plurality of high density die to gold finger routes between the flip chip die and a gold finger of the plurality of gold fingers.

7. The DIMM according to claim 1, for the device that includes the second die, wherein the second die is connected to the high density package substrate via the connection pads that include pillars, further comprising:
a further die connected to the second die on a side opposite to the high density package substrate via Through the Silicon Vias (TSV).

8. A dual in-line memory module (DIMM) comprising:
a high density package substrate including a plurality of connectors for communicatively interconnecting the DIMM to a system; and
a device including at least one of
a plurality of stacked wirebond memory dies, wherein each of the plurality of stacked wirebond memory dies includes a plurality of wirebonds and associated wirebond pads to directly interface with the high density package substrate, and
a flip chip controller application specific integrated circuit (ASIC) die including a plurality of connection pads to directly interface with the high density package substrate,
wherein a connector of the plurality of connectors is directly connected to the device respectively via at least one of a wirebond of the plurality of wirebonds and a connection pad of the plurality of connection pads.

9. The DIMM according to claim 8, wherein the plurality of connectors include a plurality of gold fingers.

10. The DIMM according to claim 8, for the device that includes the plurality of stacked wirebond memory dies and the flip chip controller ASIC die, further comprising:
a plurality of high density die to die routes between a stacked wirebond memory die of the plurality of stacked wirebond memory dies and the flip chip controller ASIC die.

11. The DIMM according to claim 8, for the device that includes the flip chip controller ASIC die, wherein the connectors include gold fingers, further comprising:
a plurality of high density die to gold finger routes between the flip chip controller ASIC die and the gold fingers.

12. A method of implementing a dual in-line memory module (DIMM), the method comprising:
attaching a device including at least one of
a first die to a high density package substrate by directly interfacing a plurality of wirebonds and associated wirebond pads of the first die with the high density package substrate, wherein the high density package substrate includes a plurality of connectors for communicatively interconnecting the DIMM to a system, and
a second die to the high density package substrate by directly interfacing a plurality of connection pads of the second die with the high density package substrate; and
directly connecting a connector of the plurality of connectors to the device respectively via at least one of a wirebond of the plurality of wirebonds and a connection pad of the plurality of connection pads.

13. The method of claim 12, for the device including the first die and the second die, further comprising:
interconnecting the first die to the second die by a plurality of high density die to die routes.

14. The method of claim 12, for the device including the second die, further comprising:
interconnecting the second die to a connector of the plurality of connectors by a plurality of high density die to connector routes.

15. The method of claim 12, for the device that includes the first die, wherein the first die is a wirebond die, and wherein attaching the device including the wirebond die to the high density package substrate by directly interfacing the plurality of wirebonds and associated wirebond pads of the wirebond die with the high density package substrate further comprises:
attaching the device including a plurality of wirebond dies including the wirebond die, wherein each of the plurality of wirebond dies includes a plurality of wirebonds to directly interface with the high density package substrate.
